(19) United States
(12) Patent Application Publication
(10) Pub. No.: US 2018/0217200 A1
(43) Pub. Date: Aug. 2, 2018

(54) POSITIONING DEVICE FOR A PARALLEL TESTER FOR TESTING PRINTED CIRCUIT BOARDS AND PARALLEL TESTER FOR TESTING PRINTED CIRCUIT BOARDS

(71) Applicant: Xcerra Corp., Norwood, MA (US)

(72) Inventors: Rüdiger Dehmel, Wunstorf (DE); Torsten Kaßbaum, Wunstorf (DE)

(21) Appl. No.: 15/747,016

(22) PCT Filed: Jun. 17, 2016
(86) PCT No.: PCT/EP2016/063989

§ 371 Date: Jan. 23, 2018

(30) Foreign Application Priority Data
Aug. 7, 2015 (DE) 10 2015 113 046.7

(51) Int. Cl. G01R 31/28; G01R 35/00; G01R 1/073

(52) U.S. Cl. CPC G01R 31/2808; G01R 1/07378; G01R 31/2812; G01R 35/005

(57) ABSTRACT

The invention relates to a positioning device for a parallel tester, a parallel tester, and a method for testing a circuit board. According to a first aspect of the invention, a positioning device is provided for fine adjustment purposes, in which the test adapter can be fastened to an inner holding piece of a holding device and the inner holding piece is supported so that it is able to move relative to the rest of the positioning device. As a bearing, only one or more swivel joints and/or one or more air bearings and/or one or more magnetic bearings is/are provided.

The present invention relates to a positioning device for a parallel tester for testing circuit boards and to a parallel tester for testing circuit boards, in particular for testing bare circuit boards.

Adapters for testing electric circuit boards are used in testing devices, which in press-like fashion, clamp a circuit board to be tested, i.e. the test specimen, between two plate-shaped elements; for contacting the testing points, an adapter is provided, which has a plurality of test needles that are arranged in the pattern of the testing points. The test specimen is pressed against the adapter so that the testing points on the test specimen are each contacted by a test needle.

Due to the way in which they are produced, the test specimens and their testing patterns are fre-quently distorted so that simply inserting the test specimen into the testing device in a predetermined position often does not produce the desired contact between the testing points and the test needles.

There are thus known testing devices in which a relative shifting and adjusting of the adapter, the test needles, and/or the test specimen can be carried out. DE 44 17 811 A1 describes an adapter that has a movable adjusting plate, which can be aligned relative to a test specimen by means of an adjusting drive. This adapter is embodied in the form of a so-called multi-board adapter, composed of several—three or five—guide plates arranged parallel to and spaced apart from one another, which are fastened so that they are spaced apart from one another by means of spacers situated at the circumference. Test needles penetrate the guide plates. The adjusting plate rests against the guide plate oriented toward the test specimen and can be moved together with this guide plate. The adjusting drive has a threaded spindle, which is directed outward and is provided with a micrometer screw, so that the adapter can be manually adjusted. Instead of a micrometer screw, a motor can also be provided, which enables a mechanical movement.

DE 43 42 654 A1 has disclosed a testing device in which the circuit board to be tested is adjusted on the testing device by being moved by means of drive motors. Each of these drive motors is contained in a separate hand-held housing that is provided for being detachably connected to the housing. These testing devices do not have separately embodied adapters and the entire testing device is especially embodied for this adjusting device.

JP 4-38480 A has disclosed an automatic adapter particularly for two-sided testing of electric circuit boards, which has an adapter body and a number of test needles that penetrate the adapter body; by means of a micro-adjustment device, the circuit board can be finely adjusted relative to the test needles through a relative movement between the circuit board and the test needles; the adjusting device has a needle guide plate in which the ends of the test needles with which the testing points are to be contacted are supported in guide bores that are arranged in the pattern of the circuit board's testing points to be tested. A helical drive that is externally mounted to the adapter is provided for moving the adjusting device.

JP 63-124969 A has disclosed an automatic adapter for testing electric circuit boards in which an external helical drive is likewise used to adjust the relative position between the circuit board and the test needles.

EP 831 332 B1 discloses an adapter for testing electric circuit boards, which has an adapter body and a number of test needles that penetrate the adapter body. Inside the adapter body, there is an adjusting device for adjusting the test needles in relation to testing points provided on the circuit board by means of a relative movement between the circuit board and the test needles; the adjusting device has a needle guide plate in which the ends of the test needles—with which the testing points are to be contacted—are supported in guide bores that are arranged in the pattern of the circuit board's testing points to be tested.

The adjusting device is arranged inside the adapter body.
The relative alignment of an adapter relative to a circuit board to be tested is subject to the following constraints:
The adapters and the test heads that are connected to the adapters are heavy. If the adapters and test heads are to be moved, correspondingly powerful forces are required.
According to EP 831 332 B1, the movement takes place inside the adapter, with parts of the adapter being moved relative to one another. This reduces the mass that has to be moved. The adapter is intrinsically mobile, though. The adapters must, however, transmit powerful compressive forces with which the adapters are pressed against the circuit board to be tested so that each individual contact is acted on with a pressure that is sufficient to produce an electrical contact.
In one-sided testing devices, the circuit board could be moved instead of the adapters. But since the currently standard testing devices must be able to perform a two-sided test, a movement of the circuit board is not sufficient to completely align the circuit board testing points relative to the contact points of the adapters.
The alignment must be carried out very precisely. The tolerance must be at least less than half the diameter or half the width of the smallest circuit board testing points of a circuit board to be tested. Currently, the width of the smallest square pad fields of bare circuit boards is approximately 20 μm
Another goal with every testing device is to test as many circuit boards as possible as quickly as possible. For this reason, the alignment of the adapters relative to the circuit board to be tested should take place as quickly as possible.
When aligning the adapters relative to a circuit board in a testing device, it is necessary to take into account and correspondingly compensate for both linear deviations and a different rotational position of the circuit board relative to the respective adapter.
The positioning device should be embodied as simply as possible so that it permits a safe and reliable positioning over the long term and does not incur high maintenance costs.

The object underlying the invention is to create a positioning device for a parallel tester for testing circuit boards, which permits a simple fine adjustment between a circuit board to be tested and an adapter of the parallel tester and in which it is also possible to align a relative rotational position between the adapter and the circuit board to be tested.

Another object of the present invention lies in creating a positioning device and a parallel tester, which solve one or more of the problems explained above.

One of the objects is attained by a subject of the independent claims. Advantageous embodiments are indicated in the respective dependent claims.

A positioning device according to the invention is provided for a parallel tester for testing circuit boards with a test adapter that has a plurality of contact elements in order to be able to simultaneously contact a plurality of circuit board testing points of a circuit board to be tested.

The positioning device has a holding device, which is embodied with an inner holding piece to which a test adapter can be fastened. The inner holding piece is supported so that it is able to move relative to the rest of the positioning devices. Supports are provided in the form of one or more swivel joints and/or one or more air bearings or magnetic bearings.

With conventional ball bearings or roller bearings, at the transition from a resting position into a movement, it is always necessary to overcome a static friction. In the present positioning device, the swivel joints are solid swivel joints in which the swiveling is produced only through a bending of the solid body. Such swivel joints do not experience any static friction of the kind that occurs, for example, in hinges or the like. Such static friction also does not occur in air bearings and magnetic bearings. Because the inner holding piece is supported exclusively with one or more swivel joints and/or one or more air bearings or magnetic bearings, it can be moved without having to overcome a static friction. This is significantly advantageous when adjusting small distances (e.g. ≤10 μm). The support of the inner holding piece in the positioning device is thus completely free of static friction and permits a very precise adjustment of the test adapter.

Preferably, the inner holding piece and thus the test adapter is supported in a plurality of ways so that the inner holding piece or the test adapter is supported so that it is able to execute a translatory motion in at least one direction in a plane and is able to rotate around a rotation axis. The positioning device can have an outer holding piece and a middle holding piece, where the outer holding piece is coupled to the middle holding piece by means of a swivel joint and the middle holding piece is coupled to the inner holding piece by means of another swivel joint. The swivel joints are preferably positioned at approximately diametrically opposite locations on the middle holding piece. By means of this, it is possible to execute an approximately linear movement of the inner holding piece relative to the outer holding piece through a swiveling motion around the two swivel joints.

The positioning device can be embodied in the form of a y-positioning device with a linearly adjusting positioner for positioning the test adapter relative to the circuit board in at least a y-direction in the plane of the contact elements of the test adapter.

This y-positioning device has two linearly adjusting positioners, which are arranged approximately parallel to and spaced a predetermined distance apart from each other so that with a different actuation of the two approximately parallel-oriented positioners, a relative rotational movement is executed between the test adapter and a circuit board to be tested.

The invention is based on the realization that the rotational movements for the alignment of the adapter relative to the circuit board to be tested only require a small maximum angular range from approximately 0.5° to 1°. As a rule, a maximum rotation range of 0.75° is sufficient. For this reason, the inventors of the present invention have realized that two linearly adjusting positioners for positioning the test adapter relative to the circuit board, which positioners are positioned approximately parallel and spaced a predetermined distance apart from each other, can be used not only to adjust the position of the adapter relative to the circuit board in the linear direction, which extends parallel to the linear positioners, but also to adjust the position of the adapter in a rotation direction about a rotation axis perpendicular to the plane of the circuit board.

In order to bring the pattern of circuit board testing points of a circuit board to be tested into agreement with the pattern of contact points of the test adapter, it is sufficient to bring two corresponding points in the pattern of circuit board testing points into agreement with corresponding points of the test adapter. This also means that two corresponding points of the circuit board can be detected by means of a camera and then the two linear positioners can be actuated so that the corresponding points are brought into coincidence. Slight deviations of the circuit board with regard to the test adapter can thus be corrected quickly and very precisely.

The positioning device preferably has linearly adjusting positioners, which are embodied in the form of linear motors [sic—linear elements?] that are moved relative to each other when the linear motor is actuated. There is an air gap between the rotor and stator so that when a linear motor is actuated, it is not necessary to overcome any static friction. The linear motors are preferably positioned so that the stator and rotor are each fastened to elements that move relative to each other so that no additional static friction-generating mechanical transmission means such as gears or the like are required in order to transmit the motion.

This positioning device can be integrated into a holding device with which the test adapter and possibly a test head connected to the test adapter can be moved. The holding device is preferably a multi-part holding device; the inner holding piece of the holding device can be attached directly to the test adapter and be situated in movable fashion with regard to an outer part of the holding device; the two positioners of the y-positioning device are coupled to the inner holding piece and outer holding piece in order to move them relative to each other.

The inner holding piece is preferably air-bearing-supported by means of an air bearing device. The air bearing device includes one or more air jets, which are provided on the multi-part holding device in the region directly below the inner holding piece. The air jets are each connected to a compressed air line so that the supply of air through the air jets produces an air cushion below the inner holding piece on which cushion the inner holding piece floats and therefore does not experience any friction resistance when moving.

Preferably, a middle holding piece is provided between the inner and outer holding piece. The middle holding piece can be coupled to the inner holding piece and outer holding piece, each by means of a respective swivel joint. The swivel joint can be embodied as a thin-walled material bridge between the respective holding pieces, which permits a limited swiveling motion. Such a swivel joint is very simple, maintenance-free, and holds the two holding pieces a predetermined distance apart from each other. The material bridge can be a connecting piece, which is composed of the same material as the different holding pieces of the holding device. Typically, this material is a steel, an aluminum, or an elastic alloy.

The linearly adjusting positioners can be linear motors. Such a linear motor has a linear rotor and a linear stator, which are moved relative to each other when the linear motor is actuated. The inner holding piece of the holding device is fastened to the rotor or stator of the two linear motors and adjacent thereto, the corresponding other part of the linear motors is fastened to the middle holding piece or the outer holding piece or to a part that is connected to the middle or outer holding piece so that when the linear motor is actuated, the inner holding piece is moved.

Instead of the swivel joints, the inner holding piece can also be arranged in freely movable fashion, but in this case, guide devices should preferably be provided, which provide frictionless guidance of the movement of the inner holding piece adjacent to the linear positioners in the linear direction. The guide devices are preferably embodied so that they permit a certain amount of play relative to the linear direction so that slight rotational movements can also be executed. The linear guides are preferably embodied with an air- or magnetic cushion or -bearing.

The positioning device can have displacement sensors to detect the movements executed by the two linearly adjusting positioners. The displacement sensor is preferably an optical sensor that scans a linear scale. The optical sensor and the scale are respectively positioned on the two parts of the positioning device and/or its holding device that are moved relative to each other by the linearly adjusting positioners. The path of the movement of each of the two linearly adjusting positioners is detected by means of this approach. Based on the signals detected by the displacement sensors, it is possible to detect both the y-position and the corresponding rotational position. These optical displacement sensors are contactless displacement sensors. In the context of the invention, it is also possible to use other contactless displacement sensors. Contactless displacement sensors do not produce any static friction. They thus facilitate the precise adjustment of an adapter. Such optical displacement sensors are able to achieve a resolution down to a few nm. Such an optical displacement sensor is particularly advantageous in connection with the above-mentioned swivel joints. These swivel joints restrict the maximum movement path of the individual moving parts of the positioning device. Thus the distance between the respective optical sensor and the scale to be scanned is established within a predetermined range, thus reliably permitting a correct scanning.

A parallel tester according to the invention for testing circuit boards with a test adapter, which has a plurality of contact elements in order to be able to simultaneously contact a plurality of circuit board testing points of a conductor particle [sic—circuit board] to be tested, has a positioning device for positioning the test adapter relative to a circuit board to be tested, which is embodied in accordance with the positioning devices explained above.

The parallel tester preferably has an x-positioning device that is embodied for positioning the test adapter relative to the circuit board in an x-direction in the plane of the contact elements of the test adapter, which direction is approximately orthogonal to the y-direction.

The x-positioning device is preferably embodied so that it moves the multi-part holding devices in the x-direction together with the adapter and in particular a test head.

A sensor can be provided, which is able to detect the relative position of the test adapter and/or the holding device in the x-direction relative to a circuit board to be tested so that based on the sensor signal of the displacement sensor, the position of the adapter relative to a circuit board to be tested can be regulated by means of a feedback loop. This enables a very exact positioning of the adapter in the x-direction, even if the x-positioning device has a very large travel distance, which is for example several times the span of the adapter in the x-direction.

The sensor for detecting the position of the test adapter and/or the holding device in the x-direction is preferably an optical sensor, which scans a scale provided on the holding device. The sensor can also be a camera, which detects the position of the holding device.

The position of the holding device is calibrated during the setup of the parallel tester, with the position of the holding device being detected by means of a camera, for example. During normal operation, the position of the holding device can be controlled, i.e. not regulated by means of a feedback loop. Basically, however, it is also possible to measure and correspondingly regulate the position of the holding device during operation.

The parallel tester preferably has at least one camera for detecting the position of the circuit board testing points.

In addition, an optical detection device or camera is provided, which can be used to scan a circuit board to be tested in a testing position. Based on images captured by the camera, the deviations of the position of individual circuit board testing points of the circuit board are determined and these deviations are used as a basis for determining an offset in the x-direction and/or y-direction relative to the rotational position. Based on this information, a determination is made as to the position into which the adapter must be brought in order to contact the circuit board to be tested.

The camera is preferably mounted on the parallel tester in mobile fashion so that it can be positioned at different locations of a circuit board to be tested. Preferably, the camera can be moved back and forth between two test stations.

Preferably, the parallel tester has an optical detection device with two cameras in order to scan both the bottom surface and top surface of a circuit board to be tested.

The parallel tester can have a z-positioning device, which is embodied for positioning the test adapter and possibly a corresponding test head in a z-direction relative to the circuit board. The z-direction extends approximately orthogonal to the plane of the contact elements of the test adapter and orthogonal to the plane of a circuit board to be tested.

The parallel tester preferably has two test adapters and in particular, two test heads, which are each positioned for testing one side of a circuit board to be tested. The two test adapters are each provided with the same positioning device, which devices are arranged in mirror-symmetrical fashion with respect to the plane of a circuit board to be tested.

According to another aspect, the invention relates to a parallel tester for testing circuit boards with a test adapter, which has a plurality of contact elements in order to be able to simultaneously contact a plurality of circuit board testing points of a circuit board to be tested. The parallel tester has a z-positioning device for moving the test adapter in a direction orthogonal to the plane of its contact elements, an x-positioning device for moving the test adapter in an x-direction in the plane of its contact elements, and a y-positioning device for moving the test adapter in a y-direction in the plane of its contact elements, which y-direction is approximately orthogonal to the x-direction. This parallel tester features two test stations, which are offset in the x-direction, and the x-positioning device is embodied with a movement path that is large enough that the x-positioning device is able to move the test adapter between the two test stations. At each test station, a conveyor device is provided for y-direction delivery and discharge of a circuit board to be tested.

Preferably, the z-positioning device and the x-positioning device are embodied to move a holding device for holding the test adapter while the y-positioning device is integrated into the holding device for moving the test adapter relative to the holding device.

The conveyor devices for y-direction delivery and discharge of a circuit board to be tested are for example embodied in the form of automatically actuatable drawers.

The parallel tester can have additional conveyor devices for delivering and/or discharging the circuit boards to be tested to and from the individual test stations. For example, these additional conveyor devices are embodied in the form of robot arms (pick-and-place unit [sic—units]).

According to another aspect of the invention, the parallel tester for testing circuit boards is embodied with a test adapter, which has a plurality of contact elements in order to be able to simultaneously contact a plurality of circuit board testing points of a circuit board to be tested. The parallel tester has a plurality of moving devices for moving at least one respective component of the parallel tester, for example a test adapter or a receiving device for a circuit board to be tested. The parallel tester features a base body composed of a mineral, ceramic, glass-ceramic, or glass-like material or composed of a concrete. Each moving device is preferably directly and/or indirectly fastened to the base body.

As a result of the moving devices being fastened to the base body, all of the moving device [sic—moving devices] permanently assume a fixed, i.e. unchanging position relative to each other. The base body is preferably rigid and heavy and in particular, preferably weights more than 200 kg, more than 300 kg, or even more than 500 kg. As a result of this, the moving devices are arranged in a fixed position relative to each other that is not very susceptible to vibration.

The use of this base body results in the fact that the relative position of the individual components that are moved with the moving devices that are affixed to the base body can be reproduced very precisely relative to one another. The components of which the moving devices are composed come in a variety of qualities. The quality differs primarily in the ability to achieve absolute positioning in the movement of the components that are moved by the moving devices. The more precise the moving devices are, the more expensive the corresponding components are. The inventors of the present invention have determined that in order to exactly align a circuit board to be tested relative to a test adapter, what matters is not the absolute precision with which a moving device moves a component, but rather the precision of the repeatability of the individual moving devices that influence the relative position of a circuit board to be tested and the test adapter. In order to achieve an exact relative precision between a circuit board to be tested and the test adapter, it is important to have a fixed frame of reference of the individual moving devices relative to one another, which in this case, is composed of the base body. It has turned out that with moving devices whose absolute movement precision is a few hundred μm, it is possible to achieve a relative repeatability of one or a few μm. In other words, once a particular position has been measured by means of a calibration device, it is then possible to resume the same position with a precision of one or a few μm. With a moving device of this kind, however, it is not necessary to execute any movement with a precision of one or a few μm. This makes it possible on the one hand to use relatively inexpensive components and on the other hand, to achieve an exact relative position. Preferably, the individual moving devices are calibrated as described in greater detail below so that the relative positions of components that are moved with the moving devices can be assumed repeatedly with the desired precision of one or a few μm.

Moving devices that influence the relative position of a circuit board to be tested and of the test adapter are the moving devices that move the test adapter and the circuit board to be tested. Other moving devices that can influence the relative position between the circuit board to be tested and the test adapter are detection devices that can be used to detect the location of the moving devices or the components that are moved by means of them (circuit board or test adapter) and to calibrate the corresponding moving devices based on the detected location. In the exemplary embodiment described below, such a detection device is embodied in the form of an optical detection device with two cameras, which are supported on the parallel tester in movable fashion.

The moving devices have one or more positioning devices; each positioning device is embodied to move the component in one movement direction and all of the movement directions of the positioning devices of each movement direction are orthogonal to one another.

The parallel tester according to the invention thus avoids the situation in which moving devices of one component depend on a moving device of another component in that the one moving device is positioned on the other moving device. With such an embodiment, the tolerances of the one moving device would be transferred to the tolerances of the moving device that is independent thereof. Consequently, a moving device either has only one, two, or three positioning devices, which are embodied with movement directions that are orthogonal to one another.

Since the moving devices are preferably fastened directly to the base body, they are each aligned with regard to the base body.

The base body is composed of a mineral, ceramic, glass-ceramic, or glass-like material or composed of a concrete. Such base bodies have a low thermal expansion. They therefore produce a very exact reference position for the individual moving devices. Since all of the moving devices are connected to the same base body, their relative position is precisely determined. In a prototype, it was possible to achieve a relative precision of 1 μm with conventional precision movement devices (carriages that can be moved on rails). In other words, the individual moving devices can repeatedly assume a position with the precision of 1 μm relative to the other moving devices.

Preferably, the parallel tester has a moving device for moving the adapter, a moving device for moving the receiving device for a circuit board to be tested, and a moving device for moving a camera. Before a particular operating phase, the parallel tester is preferably calibrated once by means of the camera; in the calibration, at least one reference point of the adapter is detected. Once the calibration has been carried out, then the adapter and the receiving device for a circuit board to be tested can be repeatedly positioned relative to each other with the precision that is made possible by means of the base body. The calibration is preferably carried out each time the parallel tester is switched on or each time the adapter is changed.

With the camera or cameras, it is thus possible to scan an adapter and a side of a circuit board to be tested. An upper camera makes it possible to scan an upper side of a circuit board to be tested and the contact side of a lower adapter. A lower camera makes it possible to scan a lower side of a circuit board to be tested and the contact side of an upper adapter. Such a camera can be used both for calibrating the position of the adapter and for detecting the position of a circuit board to be tested. Such a camera can thus be used to calibrate the position of the respective adapter and to detect the position of the circuit board to be tested. In particular, the adapter can be calibrated in its testing position (at least with regard to the x- and y-direction and its rotational position) provided that no circuit board to be tested is currently in the corresponding testing position. It is consequently possible to measure both the adapter and the circuit board to be tested in their respective testing positions. This makes it possible to achieve a very precise relative positioning between the adapter and the circuit board to be tested. This constitutes an independent concept of the invention, which can be used independent of the inventive aspects explained above. Naturally, this concept of the invention can also be combined with the other aspects described above. This is particularly true for the formation of the base body out of a rigid, preferably heavy material, which permits a precise positional reference along one or more testing positions.

The base body is preferably made of granite, glass ceramic, or silica- and/or alumina-based ceramic. Such materials have on the one hand, a low thermal expansion coefficient and on the other, a high density. Both temperature changes and vibrations have only extremely slight repercussions on the precision of the movements of the different moving devices.

Preferably, the base body is composed of a material whose thermal expansion coefficient is not greater than 5·10⁻⁶/K and preferably, is not greater than 3·10⁻⁶/K, and in particular, is not greater than 10·10⁻⁶/K.

The provision of the base body in the parallel tester fundamentally distinguishes it from conventional parallel testers, which as a rule have an approximately square or block-shaped frame in which the individual elements are arranged. A frame of this kind has the disadvantage that as a rule, elements of the device cannot be situated outside the frame, at least if they are to act on the circuit boards to be tested. In conventional parallel testers, a power supply unit or a control computer can also be situated outside the frame. It is difficult, however, for mechanically stressed parts such as an adapter, parts of the press, or elements for manipulating circuit boards to be positioned outside the frame since either the necessary static properties are lacking and/or parts of the frame hinder a movement.

The base body according to the invention is situated inside the parallel tester. All elements and parts of the parallel tester are fastened directly or indirectly to the base body. The base body thus constitutes a rigid core or a rigid internal skeleton around which all of the parts and elements of the parallel tester are arranged.

The base body is a rigid body which is composed, for example, of a mineral material, in particular granite. In this context, “rigid” means that the base body is dimensionally stable enough that over a normal processing time, it deforms by less than a few, preferably less than 1, micrometer(s).

Due to temperature changes, more powerful deformations can occur in the base body. But the temperature changes or temperature fluctuations are so sluggish that they have no influence on a normal processing time. The processing time can range from a few minutes to one hour or even a few hours.

Due to the rigidity of the base body, there is an unambiguous reference along the base body to a frame of reference or coordinate system. In other words, all of the parts that are fastened directly to the base body have a particular position relative to one another in a coordinate system, which is determined by the connecting points to the base body. Since the base body is rigid, this relative position does not change as a rule. Once this relative position is detected, then it can be used repeatedly to determine the position of the individual elements relative to one another since they are maintained due to the rigidity of the base body. The base body can thus be made of any rigid material, e.g. steel or a mineral material.

Like a spine in a skeleton, the base body extends over the majority of the longitudinal span of the parallel tester; the base body primarily extends in the horizontal direction in order to provide a corresponding moving device with the corresponding holding action in the horizontal direction. In the vertical direction, the base body preferably extends far enough that it is situated in the vertical direction in the vicinity of upper and lower test elements with which a circuit board to be tested can be tested on both sides, i.e. on an upper and lower side. Consequently, the base body preferably constitutes a kind of rear wall of the parallel tester. The individual other elements of the parallel tester, however, can extend beyond the base body in the vertical direction.

A base body embodied in the form of a rear wall can have single sections or a plurality of sections that extend forward horizontally from the rear wall.

Preferably, the base body is composed of a material that is subject to little thermal expansion, e.g. a mineral material. With a material that has a high thermal expansion such as steel, it would be necessary to recalibrate the parallel tester after each temperature fluctuation by a predetermined amount, it being necessary to determine the relative position of the elements fastened directly and/or indirectly to the base body.

Another advantage of the base body lies in the fact that all of the other elements and parts of the parallel tester are installed around it so that in principle, there is no limit to the size of the parallel tester.

According to another aspect of the invention, the parallel tester for testing circuit boards is provided with a test adapter, which has a plurality of contact elements, in order to be able to simultaneously contact a plurality of circuit board testing points of a circuit board to be tested. The parallel tester has at least one moving devices [sic—moving device] for moving the test adapter, one moving device for moving a receiving device for a circuit board to be tested, and at least one optical detection device. The parallel tester provided with a control device, which is embodied so that the optical detection device detects a circuit board to be tested in different measurement positions; position information about the circuit board in the different measurement positions is stored in memory and the circuit board and test adapter are moved into the different measurement positions in order to perform a testing procedure there. Then the control device triggers one or more testing procedures; between the several testing procedures, the circuit board and the test adapter are moved relative to each other. In this parallel tester, a particular circuit board in the measurement position is measured in advance and then the several testing procedures are carried out in succession. It is thus possible to very quickly perform the testing of a circuit board to be tested. This particularly applies to circuit boards with a plurality of panels that are each individually tested with a test adapter for each panel.

According to another aspect of the present invention, a method for calibrating a parallel tester is provided in which a detection device is used to detect the position of a test adapter in different measurement positions. Based on these detected measurement positions, control information for controlling the movement of the test adapter between the measurement positions is derived and saved in memory. The control information describes the relative movement of the test adapter and/or receiving device between the individual measurement positions.

This calibration is based on the realization that when a circuit board is contacted by a test adapter, a few measurement positions are generally required. Usually, each panel of a circuit board is tested with a different measurement position of the test adapter relative to the circuit board. During calibration, the test adapter and/or the receiving device for a circuit board to be tested is/are brought into the corresponding measurement position(s) and aligned with each other if need be.

These measurement positions are then saved in memory as control information so that during subsequent operation, once a test adapter has been correctly calibrated, it can be controlled relative to a circuit board in the other testing positions, i.e. can be moved exactly relative to the circuit board or relative to the receiving device of the circuit board without a control loop.

In the parallel tester with the base body explained above, since the relative position of the individual elements (adapter, camera, and/or circuit board to be tested) are held in a very stable and precise fashion for a normal processing time, the calibration of the adapter can be carried out simply by means of the camera provided on the parallel tester. By means of the calibration, the position of the adapter relative to the remaining elements of the parallel tester can be determined very precisely. In conventional parallel testers, it is known to calibrate the adapter using a separate testing device, which often has separate calibration elements such as glass plates, which, in order to perform the calibration, must be mounted in the parallel tester in order to produce a very exact reference of the individual elements. In the present parallel tester, it is not necessary to use a separate testing device or separate testing means. Not only does this eliminate the need for purchasing this separate and very expensive testing device, but also—since the cameras provided in the parallel tester for scanning the circuit boards can also be used for the calibration of adapters, the calibration can be carried out very quickly. In the first prototypes of this parallel tester, the calibration procedure for calibrating the adapter lasts about 20 seconds. Such a short calibration procedure can be performed repeatedly in the parallel tester without negatively affecting the throughput of the parallel tester. Preferably, the calibration procedure of the adapter can be repeated at least once every hour, preferably after half an hour elapses or after 20 minutes elapse, or after 10 minutes elapse. Within the time interval in which such a calibration of the adapter is performed, the relative position does not change perceptibly thanks to the rigid base body.

Because of the quick repetition of the calibration of the adapter or adapters, it is not necessary to provide additional mechanical stabilization for the parallel tester, e.g. by placing it in an air-conditioned room. A gradual, slow change in the base body and thus in the relative positions due to temperature fluctuations therefore does not interfere with the operation of the parallel tester, provided that no changes of the base body by more than a few micrometers take place between two successive calibration procedures.

Through this combination of the rigid base body in connection with the calibration procedure—in which a camera provided in the parallel tester is used, whose position, just like the position of the adapter, is maintained with reference to the base body—, a highly precise and stable parallel tester is inexpensively achieved.

Preferably, a parallel tester with two test adapters is used, which are able to contact an upper side and a lower side of a circuit board simultaneously. In test adapters of this kind, it is advantageous to provide two detection devices for detecting the position of the circuit board or the receiving device for a circuit board to be tested and/or the position of the test adapter. This detection device can thus preferably include two cameras. The cameras are arranged pointing in opposite directions so that one camera can scan the upper side of a circuit board to be tested and the other camera can scan the lower side of a circuit board to be tested and/or these cameras can scan the lower test adapter or the upper test adapter. The two cameras are preferably calibrated with each other when the parallel tester is switched on. The calibration can take place in that the one camera optically scans the location of the other camera and thus the positions of the two cameras relative to each other are determined and aligned if need be.

The simplest and commonest detection device for detecting the relative position of a test adapter and of a circuit board to be tested and/or of the receiving device for receiving the circuit board include(s) one or two cameras. There are also known methods with which the position of a test adapter relative to a circuit board is determined in that the test adapter is pressed against the circuit board one or more times in different relative positions and in that the position of the parallel tester relative to the circuit board to be tested is detected based on the contacts produced. Such a detection device can be used instead of an optical detection device for detecting the position of a test adapter relative to a circuit board to be tested. The same is true for all of the exemplary embodiments explained herein.

The test adapter of the parallel tester can be embodied as a universal adapter. Such a universal adapter maps a pattern of circuit board testing points of a circuit board to be tested onto a uniform grid of a universal test head. The universal test head is used for all types of circuit boards. If the parallel tester is to contact a different type of circuit board, then it is only necessary to exchange the universal adapter, which can be coupled to the universal test head. As a rule, such a universal adapter is composed of a plurality of layers of guide plates, which can be arranged spaced apart from one another and in which feedthroughs are provided. Contact needles extend through the feedthroughs and their ends protrude from the respective outer guide plates of the adapter and can thus contact the contact points of the uniform grid of the universal test head as well as the contact points or circuit board testing points of a circuit board to be tested.

On the other hand, a test adapter in the form of a so-called “dedicated test adapter” can also be provided. Such a dedicated test adapter has contact elements, which are arranged in a pattern that corresponds to the pattern of the circuit board testing points of a circuit board to be tested. The contact elements are connected directly to cables that lead to a set of testing electronics. As a rule, the connection between the cables and the contact elements is embodied in the form of a soldered connection. Such a dedicated test adapter is generally produced in that a plate composed of insulating material is provided with bores arranged in the pattern of circuit board testing points of the circuit board to be tested, with one of the contact elements being inserted in each of the bores. If the circuit board to be tested only has contact points in the form of through-hole plating, then the pattern of bores of this through-hole plating can be directly used to produce the test adapter.

The overall height of a universal adapter is significantly less than that of a dedicated adapter. In order to be able to compensate for this overall height, it is advantageous if a vertical positioning device (z-positioning device) has a movement stroke of at least 80 mm, preferably at least 100 mm or at least 120 mm, and in particular at least 150 mm. There are known conventional parallel testers in which both universal adapters and dedicated test adapters can be used. These parallel testers have an electrical terminal area for a dedicated test adapter. A universal adapter is coupled to this terminal area by means of a complex circuit board that has a large area and is composed of many layers, with the terminal area and universal adapter being offset from each other in the horizontal direction. This offset is bridged-over by the multi-layered complex circuit board.

The parallel tester according to the invention is provided with a basic electrical grid, which has contact points in a uniform grid. A universal adapter can be placed onto this basic grid in the usual way. Thanks to the large stroke of the vertical positioning device, it is possible to place a contacting cassette onto the basic grid, which cassette has contact elements that are each for the connection of a respective cable. The cables are connected to the contact elements on the side of the contacting cassette oriented away from the basic grid. These cables then lead to the contact elements of the test adapter. Between the basic grid and the dedicated test adapter, there is thus enough space for the cables and for the contacting cassette for contacting the cables to the basic grid.

One of the parallel testers explained above can be used to test circuit boards, in particular bare circuit boards. To this end, a universal adapter or a dedicated test adapter can be used.

The parallel tester can be embodied so that the circuit boards are only tested for breaks and/or short circuits. Such a testing method is generally used for testing bare circuit boards since in this case, the individual connections only have to be tested with regard to whether they do not have any breaks or are not short-circuited with another conductor. The testing of bare circuit boards is therefore also understood here to mean the testing of circuit boards with so-called embedded components, which include, for example, resistors, capacitors, or diodes.

Basically, it is also possible for the parallel tester to be used for testing equipped circuit boards. Equipped circuit boards generally have integrated circuits. To test equipped circuit boards, function tests (in-circuit tests) are performed in which complex signals are applied to the conductors of the equipped circuit board and the reaction of the equipped circuit board to these complex signals is measured.

The testing of bare circuit boards differs from the testing of equipped circuit boards primarily in that significantly more contact points or circuit board testing points have to be contacted at the same time. In comparison to this, very few contact points are contacted when testing equipped circuit boards, but these are acted on with more complex electrical signals. When testing bare circuit boards, it is often necessary to contact more than 1000 or more than 5000 or even more than 10,000 circuit board testing points at the same time.

Circuit boards are often produced with a plurality of panels. A panel is a particular pattern of contact points and conductors. After the testing, the circuit board with a plurality of panels is divided into the individual panels that then each constitute a separate circuit board. The panels of a circuit board are identical. A circuit board with a plurality of panels can be tested with a test adapter that has contact elements only for the contact points of a single panel; the test adapter contacts the respective panels of the circuit board in succession. To this end, the test adapter is brought into contact with the respective panels through an incremental relative movement of the test adapter relative to the circuit board to be tested. The parallel tester explained above can be used for successively testing a plurality of panels. This is also referred to as “stepping.”

The stepping can be executed with the x-positioning device in the x-direction, which moves the test adapter in the x-direction. In the y-direction, the stepping can be carried out with the conveying direction [sic—conveying device] for moving the circuit board to be tested in the y-direction.

This conveyor device for conveying the circuit board in the y-direction moves the circuit board between a testing position and an exchanging position. The exchanging position is situated outside the region that is covered by the test adapter and the holding device encompassing the test adapter so that a circuit board is freely accessible in the exchanging position. In the exchanging position, the circuit board can, for example, be picked up by a robotic arm or exchanged manually.

As explained above, the y-positioning device can be embodied with an air bearing device. The air bearing device produces an air cushion during the actuation of the y-positioning device. During the testing, preferably no air cushion is produced so that the test adapter is fixed in position by frictional engagement. The use of the air bearing device for fixing the position of the test adapter constitutes an independent concept of the invention, which can be used independent of the inventive aspects explained above.

In the explanations above, references are made to a coordinate system with an x-, y-, and z-axis. The z-axis extends in the vertical direction. The x- and y-axes define the horizontal plane. In the context of the invention, the x- and y-axes can be interchanged with each other.

The aspects explained above can also be implemented independently of each other or also in any combination in a parallel tester.

The invention will be explained in greater detail below in conjunction with the accompanying drawings. In the drawings:

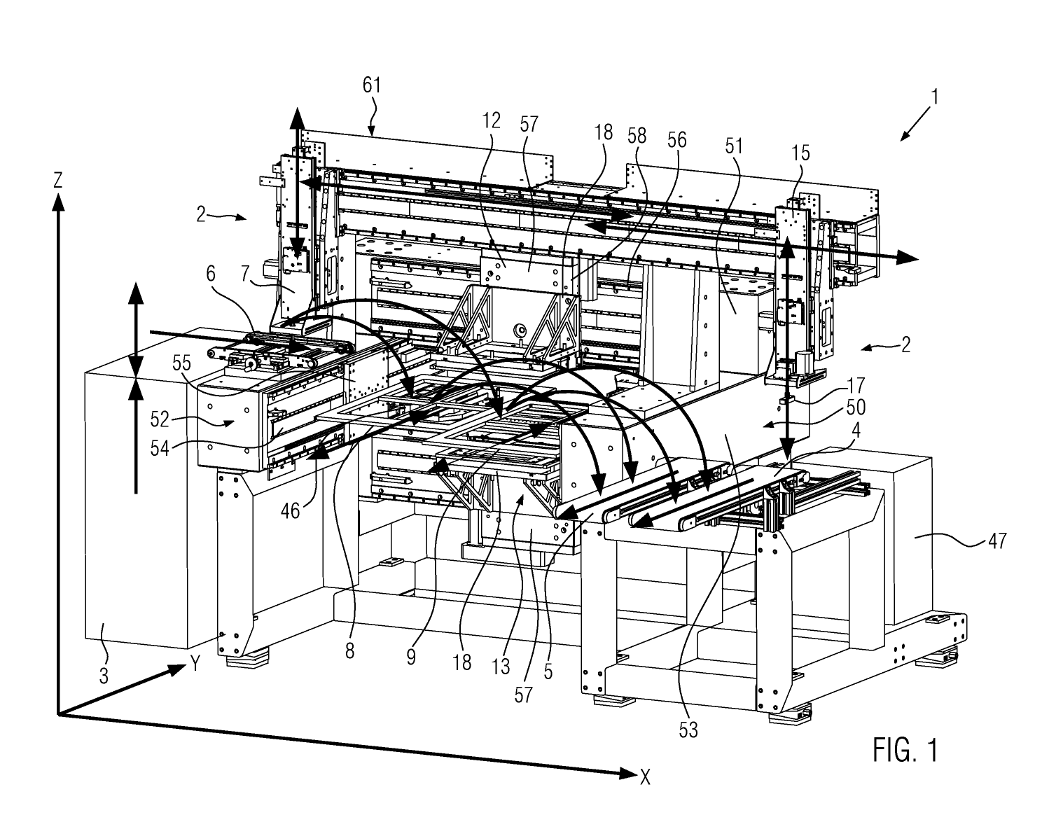

FIG. 1 is a perspective view of a parallel tester with two test stations and a lower and upper test head with adapter,

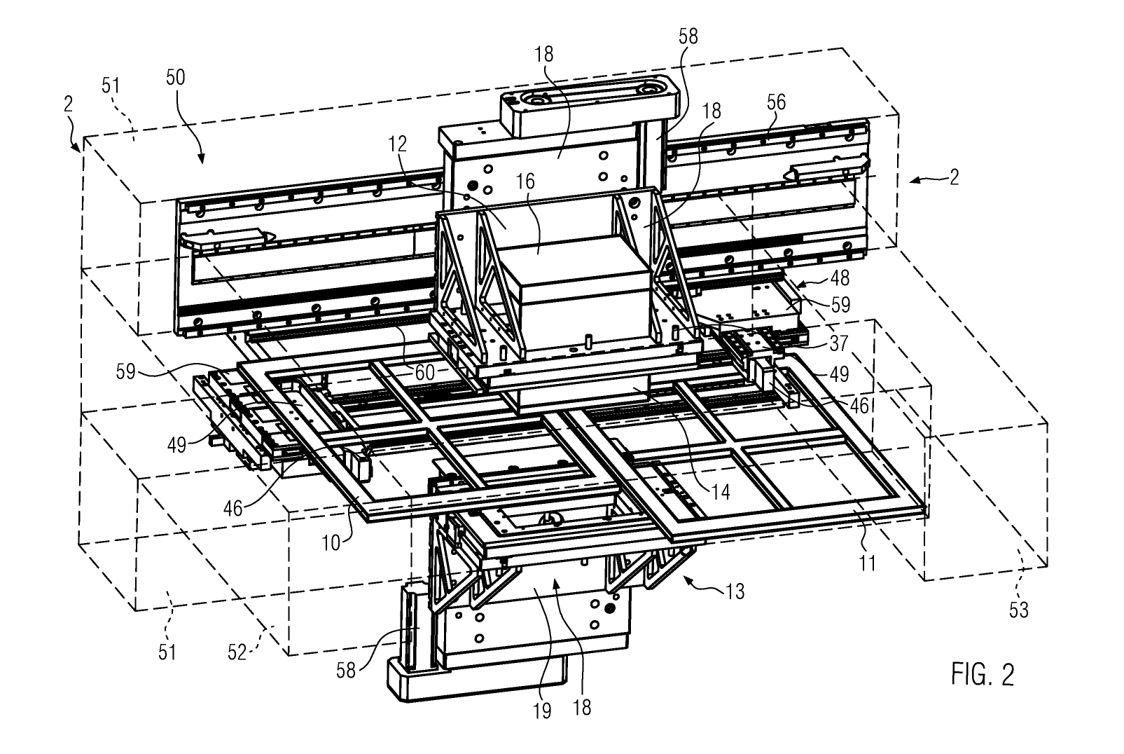

FIG. 2 is an enlarged depiction of two test stations of the testing device from FIG. 1,

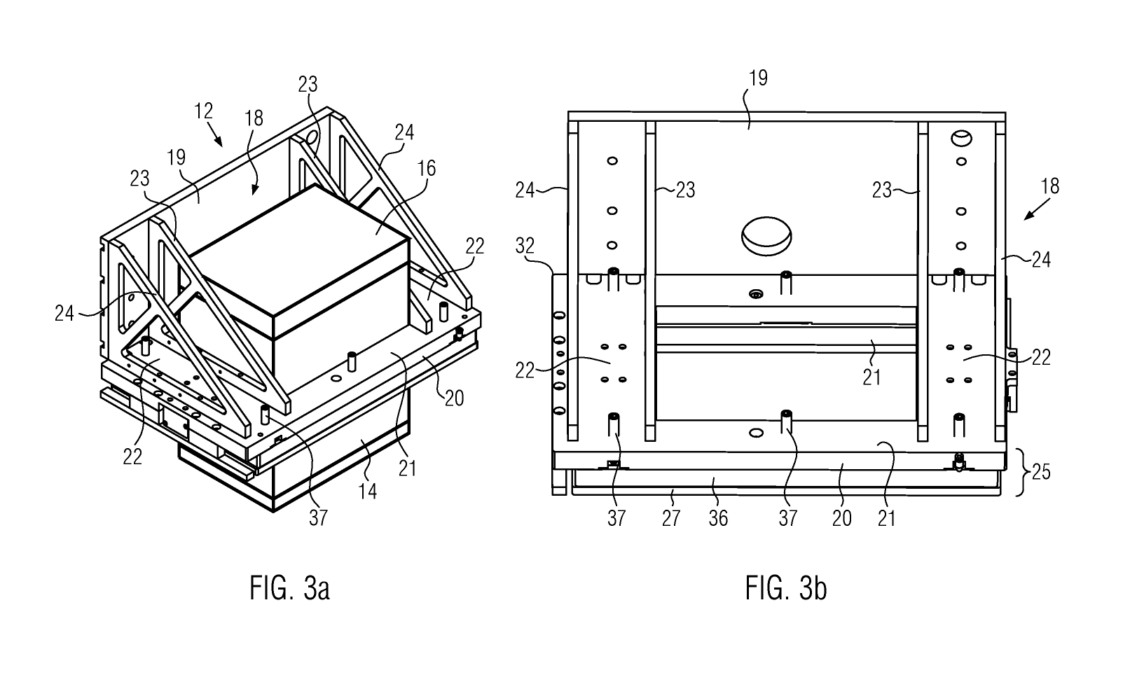

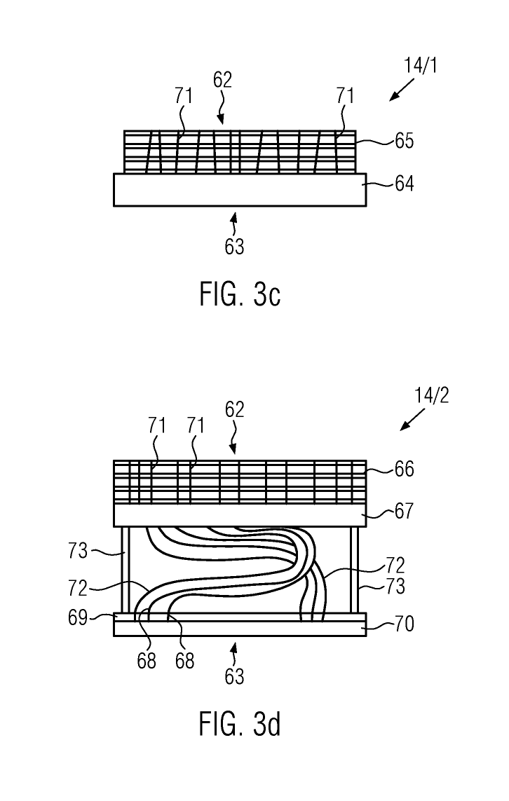

FIG. 3a-3d show a holding device for holding a test adapter and a test head, viewed from the front with and without the test head, as well as a universal adapter (FIG. 3c) and a dedicated test adapter, each in a perspective view,

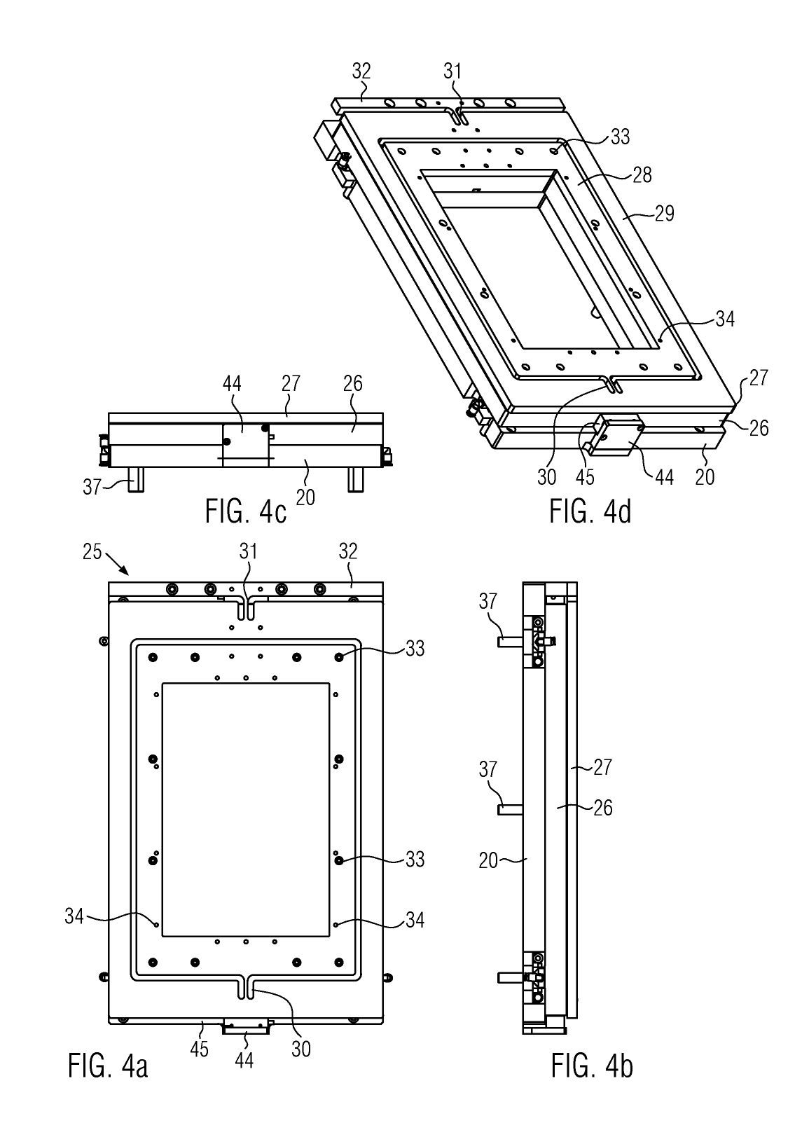

FIG. 4a-4d each show a holding frame of the holding device from FIG. 3 in a top view (FIG. 4a), a longitudinal view (FIG. 4b), a front view (FIG. 4c), and a perspective view (FIG. 4d), and

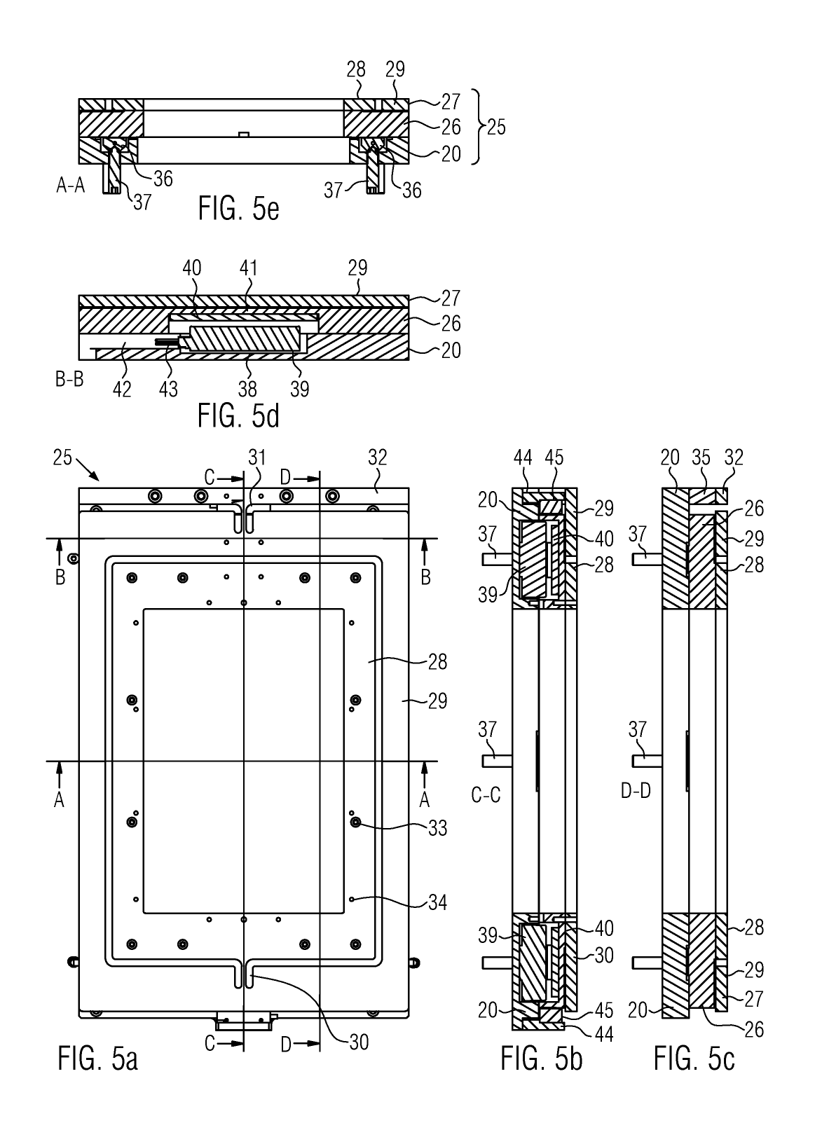

FIG. 5a-5e show the holding frame from FIG. 4a in a top view (FIG. 5a) together with a plurality of section lines A-A, B-B, C-C, and D-D and the corresponding sectional views, and

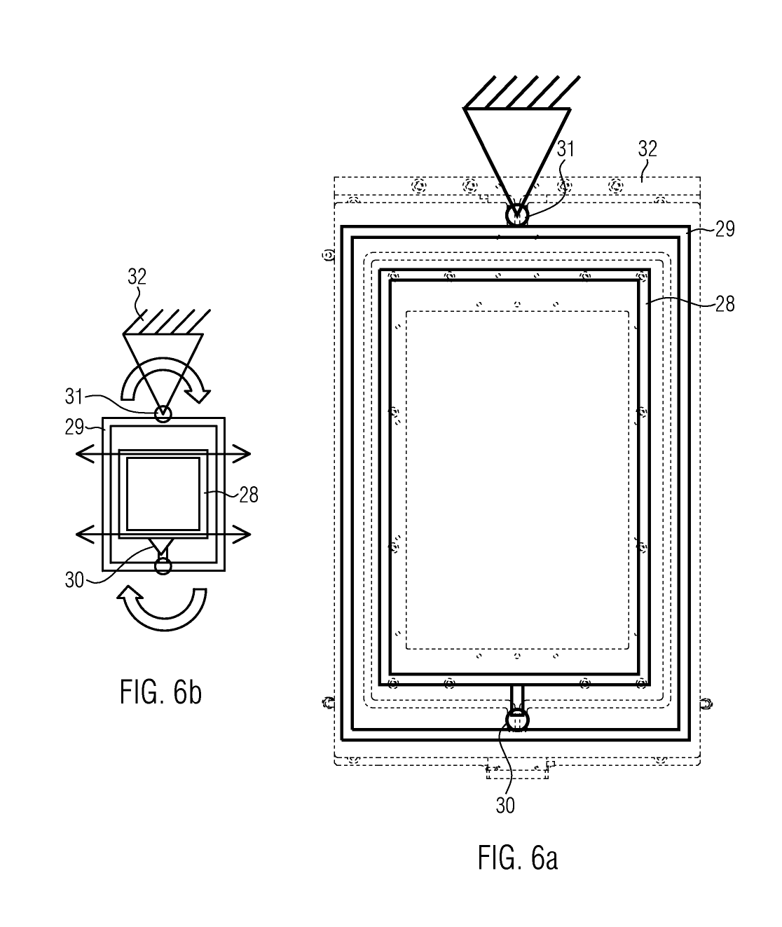

FIG. 6a shows the holding frame from FIG. 5a with a schematic frame structure, and

FIG. 6b schematically depicts a block circuit diagram of the frame and the articulated link-age arrangement of the holding frame.

A parallel tester 1 according to the present invention has a base body 50, which is made of granite (FIG. 2). The base body 50 is composed of two integrated longitudinal beams 51, which form a rear wall 2, and two transverse beams 52, 53 extending forward from the rear wall 2. The two transverse beams 52, 53 are affixed to the longitudinal beams 51 so that they form a coherent component. The transverse beams 52 can be fastened to the longitudinal beams 51 by means of a screw connection with a powerful frictional engagement. Preferably, the base body 50 is composed of a single piece.

In the present exemplary embodiment (FIG. 1), a hopper 3 for untested circuit boards is located on the left when viewed from the front, adjacent to the rear wall 2, and a conveyor belt for good circuit boards 4 and a conveyor belt for bad circuit boards 5 are located on the right, adjacent to the rear wall 2. In this parallel tester 1, the circuit boards to be tested are moved from left to right.

Naturally, the parallel tester 1 can be embodied in such a way that the hopper 3 for untested circuit boards and the conveyor belts 4, 5 for tested circuit boards are situated on opposite sides or also are situated above and below. The parallel tester 1 is situated in a housing (not shown) that encloses all of the moving parts of the parallel tester so that during operation, operators cannot get into the movement region of the moving parts. Only the conveyor belts 4, 5 lead out of the housing so that an operator can remove the tested circuit boards from the conveyor belts 4, 5. The conveyor belts 4, 5 can also basically be coupled to a collecting device that automatically collect [sic—collects] the positively and negatively tested circuit boards in different containers.

The horizontal direction parallel to the rear wall 2 from left to right is hereinafter referred to as the x-direction. The horizontal direction that extends perpendicular to the rear wall 2 from the front to the rear wall is hereinafter referred to as the y-direction. The vertical direction parallel to the rear wall 2 from the bottom to the top is hereinafter referred to as the z-direction. A corresponding coordinate system is shown in FIG. 1.

The hopper 3 for the as yet untested circuit boards has a lift with which the stack of untested circuit boards can be gradually lifted. At the upper edge region of the hopper 3, there is a separating device 6 provided on the transverse beam 52, which withdraws the top circuit board of the stack of untested circuit boards from the hopper 3 and supplies it to a robotic arm 7.

The robotic arm 7 is embodied so that it can be moved in the vertical direction (z-direction). At its lower end, the robotic arm 7 has a vacuum gripper, which is embodied for picking and placing circuit boards. The vacuum gripper can be adjusted in the y-direction on the robotic arm 7 so that it can grasp different-sized circuit boards centrally. On the rear wall 2, there is an x-axis 61 along which the robotic arm 7 is supported so that it can move in the x-direction.

On the two transverse beams 52, 52 [sic—52, 53], two drawer mechanisms 8, 9 are mounted in the same plane so that in each, a respective frame-shaped drawer 10, 11 for receiving a circuit board can be moved a certain distance forward and back again in the horizontal direction relative to the rear wall 2 (FIG. 2). The drawer mechanisms 8, 9 each include a rail 54 extending in the horizontal direction, which is fastened to one of the two transverse beams 52, 53 on the side oriented toward the opposite transverse beam. A respective plate-shaped carriage 55 to which one of the frame-shaped drawers 10, 11 is fastened is guided in movable fashion on each of the rails 54. The drawer mechanisms 8, 9 each constitute a respective moving device. The drawer mechanisms 8, 9 move the frame-shaped drawers 10, 11 with a precision of approximately 100 μm.

In the region above and below the two drawers 10, 11, a respective holding device 12, 13 is provided.

The holding devices can be moved along the rear wall 2 in the x-direction so that the two holding devices 12, 13 can each be positioned above or below the two drawer mechanisms 8, 9. On each of the longitudinal beams 51, a respective rail 56 is horizontally fastened for guiding each holding device 12, 13. On each rail 56, a respective holding device carriage 57 is guided in the x-direction so that it can be moved by means of a corresponding drive unit. This constitutes a moving device in the x-direction.

On the holding device carriage 57, the holding devices 12, 13 are each arranged so that they can be moved in the z-direction by a vertically extending linear drive unit 58. The linear drive 58 is embodied in the form of a spindle drive in order to be able to generate powerful forces. These elements for moving the holding devices each constitute an additional moving device for a movement in the z-direction, which is supplemented by a positioning device in the y-direction that will be explained in greater detail below.

The linear drive 58 includes guide rails (not shown), which extend in the vertical direction and on which the holding devices 12, 13 are guided. Since the moving devices in the x-direction and in the z-direction are fastened to the outside of the base body 50, there are no structural limits for the length of the respective movement paths. As a result of this, the movement path in the vertical direction (=z-direction) can be selected as being large enough that the holding devices 12, 13 can hold a universal adapter 14/1 (FIG. 3c) or a dedicated adapter 14/2 (FIG. 3d). A dedicated adapter requires significantly more space to accommodate cables—which extend from contact elements to a set of testing electronics—than is required by a universal adapter. In the present exemplary embodiment, the movement path of the vertical moving device is approximately 120 mm.

An adapter 14 and a test head 16 are situated in each of the holding devices 12, 13. In FIG. 1, the parallel tester is shown without an adapter 14 and without a test head 16. In FIG. 2, for the sake of a simpler graphic depiction, the adapter 14 and test head 16 are only shown in the upper holding device 12, with no adapter and test head shown in the lower holding device 13. During operation, an adapter and a test head are naturally provided in the lower holding device 13.

The test adapters 14 each have a plurality of needle-shaped contact elements, which protrude from the adapter in the pattern of contact points of a circuit board to be tested. These contact points of a circuit board to be tested are referred to hereinafter as circuit board testing points. The contact elements of the upper adapter 14 point downward and the contact elements of the lower adapter point upward so that a circuit board to be tested can be positioned between the two adapters 14 and the upper side and lower side can each be contacted simultaneously by a respective one of the adapters 14.

On their side oriented away from the circuit board to be tested, the adapters 14 are each connected to one of the test heads 16. The test heads 16 contain testing electronics with which measurement signals are supplied to the individual contact elements of the adapters 14. With these measurement signals, it is possible for example to perform a resistance measurement between two contact elements of an adapter 14. It is also possible, however, to supply complex measurement signals with which it is possible to carry out capacitive measurements or measurements of complex conductances. When testing bare circuit boards, however, preferably only measurements for measuring the ohmic resistance between two circuit board testing points are carried out. The test heads are embodied with a basic grid, which has contact points arranged in a uniform grid. The adapters 14 thus map the pattern of contact points of a circuit board to be tested onto the pattern of contact points of the basic grid. A plurality of contact points of the basic grid can be connected to one another; the contact points of the basic grid that are connected to one another are each connected to a respective individual input of the evaluation electronics. The contact points of the basic grid can be respectively connected in pairs, in threes, in fours, or in mixed combinations. In this regard, reference is made to U.S. Pat. No. 6,154,863 A and EP 0 838 688 A.

A universal adapter 14/1 is schematically depicted in FIG. 3c. This universal adapter has a side 62 oriented toward the test specimen (circuit board to be tested), which side is referred to hereinafter as the test specimen side. The side oriented away from the test specimen contacts the basic grid of the test head 16 and is referred to as the basic grid side 63. The universal adapter 14/1 is composed of a full grid cassette 64, which is also referred to as a spring cassette, and an adapter unit 65. The full grid cassette has spring-loaded testing pins, which are arranged in the pattern of the contact points of the basic grid. The individual spring contact pins are respectively arranged parallel to one another and perpendicular to the plane of the test specimen or the basic grid. The adapter unit has test needles 71, which are embodied, for example, in the form of rigid needles. The test needles are held by a plurality of circuit boards, which are spaced apart from one another and provided with bores so that they guide the test needles. The bores are arranged so that the individual test needles lead from spring-loaded pins of the full grid cassette 64, which are arranged in the pattern of the basic grid, to a contact point in the pattern of contact points of the test specimen. To this end, a majority of the individual test needles are as a rule oriented at an angle to the plane of the test specimen or the basic grid. The guide plate of the adapter unit 65 situated on the test specimen side 62 has bores in the pattern of contact points of the test specimen. The guide plate of the adapter unit 65, which is situated adjacent to the full grid cassette 64, has bores in the pattern of the basic grid. A test needle extends through each of these bores.

FIG. 3b shows a dedicated test adapter 14/2. This test adapter once again has a test specimen side 62 and a basic grid side 63. An adapter unit 66 and a spring pin cassette 67 are situated on the test specimen side 62. Like the adapter unit 65, the adapter unit 66 has test needles 71 and the spring pin cassette 67 has spring-loaded contact pins. In the adapter unit 66 and the spring pin cassette 67, all of the test needles and contact pins are parallel to one another and are arranged in the pattern of the contact points of the test specimen to be tested. The adapter unit 66 and the spring pin cassette 67 are thus embodied in a way that is specific to the test specimen. A cable 72 contacts each spring pin of the spring pin cassette 67 on the side oriented away from the test specimen side 62. These cables 72 constitute a cable harness; the end of each cable remote from the spring pin cassette 67 is connected to a contact pin 68. The contact pins 68 are arranged in a basic grid contacting plate 69. The basic grid contacting plate 69 has through bores into each of which a respective one of the contact pins 68 is inserted. These through bores are each allocated to a contact point of the basic grid of the test head 16. Between the basic grid contacting plate 69 and the basic grid, there is another spring pin cassette 67, which has a spring contact pin that is allocated to each contact pin 68 and electrically contacts the contact pin 68 to a corresponding contact point of the basic grid. The basic grid contacting plate 69 and the spring pin cassette 67 are connected by means of pillars 73, which keep them spaced apart so that there is room for accommodating the cables 72.

The universal adapter 14/1 has an overall height of approximately 75 mm and the dedicated test adapter has an overall height of 140 mm. So that both a universal adapter and a dedicated test adapter can be inserted into the parallel testers, the movement path in the vertical direction must be greater than the difference between the overall heights of the two adapters (=65 mm) plus a required working stroke.

The dedicated test adapter 14/2 explained above is one possible embodiment. Through the use of the adapter unit 66 and the spring pin cassette 67, it is possible to reliably produce contacts with contact points that have a high density; the spring pin cassette 67 in the test needle of the adapter unit 66 is acted on so that all of the test needles are reliably contacted. There are, however, also other known embodiments of dedicated test adapters, which have an adapter unit with test needles that have a diameter of e.g. only 0.80 μm on the test specimen side. These test needles are so thin that they bend outward when stressed and act like a spring. Instead of a spring pin cassette, a grid board is provided in which copper/lacquer wires are glued into through bores of a circuit board; on one side of the circuit board, the copper/lacquer wires are cut off in the region of the surface and this side is polished so that the cut-off surfaces of the copper/lacquer wires each constitute a contact point for the thin test needles of the adapter unit. These copper/lacquer wires can, for example, have a diameter of 0.2 mm and can be positioned in a grid spacing of 0.3 mm. The ends of the copper/lacquer wires oriented away from the adapter unit are connected to the cables. The copper/lacquer wires constitute the cables 72, which are each connected to one of the contact pins 61, which are provided on the basic grid contacting plate 69.

The two drawer mechanisms 8, 9 consequently each constitute a respective test station; in one testing procedure, the linear drives press the two adapters from above and below against a circuit board to be tested, which is situated in the test station.

When being loaded with or discharged of a circuit board, the drawers 10, 11 are moved forward, i.e. away from the rear wall 2 into an exchanging position. A drawer 10, 11 that is loaded with an as yet untested circuit board is moved rearward in the y-direction into a testing position, i.e. in the direction toward the rear wall 2. The two drawers 10, 11 are preferably alternatingly situated in the testing position and in the exchanging position so that one drawer in the exchanging position can be discharged of the already tested circuit board and can be loaded with an as yet untested circuit board and the other drawer can be tested in the testing position.

The unloading of a drawer is carried out by means of another robotic arm 15, which, depending on the result of the testing procedure performed, places a tested circuit board either onto the conveyor belt for good circuit boards 4 or onto the conveyor belt for bad circuit boards 5. The conveyor belts 4, 5 transport the tested circuit boards into corresponding collecting receptacles (not shown).

The robotic arm 15 can once again be moved in the vertical direction (z-direction) and in the x-direction along the x-axis 61 and at its lower end, has a gripper device 17 in order to pick and place circuit boards. The gripper device 17 is embodied as a vacuum gripper. The gripper device 17 does not require adjustment in the y-direction since in order to pick up the circuit boards, the carriages 8, 9 are correspondingly positioned in the y-direction so that the gripper device 17 can grip the corresponding circuit board center.

There are circuit boards with a plurality of panels, in which the individual panels are arranged so that they are rotated relative to one another or are mirror-symmetrical to one another. During testing, these circuit boards must be placed in different rotational positions relative to the test adapter. To this end, the gripper device 17 of the robotic arm 15 has a motor with which the gripper device 17 can be rotated around a vertically oriented rotation axis. This makes it possible to rotate a circuit board that is being gripped by the gripper device 17. During operation, it is mainly practical to lift circuit boards from the respective drawer 8, 9, to rotate them by 90 degrees or 180 degrees, and to place them back into the drawer in order to test other panels.

The holding devices 12, 13 each have a support rack 18 (FIGS. 2, 3a, and 3b). The support rack 18 has a rear wall 19 and a horizontal support rack frame 20 with two longitudinal struts 21 extending in the x-direction and transverse struts 22 extending in the y-direction. The transverse struts 22 are each connected to the rear wall 19 by means of two side wall elements 23, 24 that are triangular in the side view 3.

The support rack frame 20 is a component of a holding frame 25. The holding frame 25 has an essentially three-layered construction; a first layer is composed of the support rack frame 20, a second layer is composed of a load frame 26, and a third layer is composed of a control frame 27. The load frame 26 and the control frame 27 are positioned on the side of the support rack frame 20 oriented away from the side wall elements 23, 24.

The control frame 27 has an inner control frame part 28 and an outer control frame part 29. The inner and outer control frame parts 28, 29 are rectangular frames when viewed from above; the inner control frame part 28 is spaced a short distance apart from the inside of the outer control frame part 29. The inner control frame part 28 is connected to the outer control frame part 29 by means of a thin-walled connecting piece 30; the connecting piece 30 extends part-way into the region of the outer control frame part 29.

On the end that is oriented away from the connecting piece 30, the outer control frame part 29 is connected to an outer connecting piece 31 with an end strip 32. The end strip 32 is attached in stationary fashion to the support rack frame 20 by means of screws via an intermediate strip 35. The intermediate strip 35 has the same height as the load frame 26.

The inner control frame part 28 has bores 33 for the attachment of the inner control frame part 28 to the load frame 26 by means of screw connections. In addition, the inner control frame part 28 has positioning bores 34 for positioning and fastening one of the test adapters 14, 15.

The end strip 32, the outer control frame part 29, and the inner control frame part 28 are made of a steel plate; only the intermediate spaces between these elements 28, 29, 32 are milled out, leaving behind the inner and outer connecting pieces 30, 31 that form the connection between the corresponding parts. In the vertical projection, the control frame parts 28, 29 approximately cover the load frame 26.

The outer control frame part 29 can be swiveled relative to the end strip 32 by means of the outer connecting piece 31; the swiveling range is +/−2°. In the same way, the inner control frame part 28 can be swiveled relative to the outer control frame part 29 about the inner connecting piece 30 through an angular range of +/−1.5°.

Consequently, the inner control frame part 28 is supported so that it can swivel in two ways relative to the end strip 32 by means of the two connecting pieces 30, 31. The inner control frame part 28 can therefore be slid in linear fashion in the y-direction (FIG. 5a) relative to the end strip and rotated a little.

The load frame 26 rests on the support rack frame 20, which is a component of the support rack 18. In the support rack frame 20, several air jets 36 are provided on the side oriented toward the load frame 26; the nozzle opening of the air jets 36 points toward the load frame 26. The air jets 36 are each connected to a compressed air hose (not shown). The air jets 36 are each connected to a threaded pin 37 on the side oriented away from the nozzle mouth. The threaded pins 37 are each screwed into a corresponding threaded bore in the support rack frame 20 and are used to adjust the height of the air jets 36.

The vertical position of the air jets 36 is preferably set so that the load frame 26 is spaced a few tenths of a millimeter from support rack frame 20. By blowing compressed air through the air jets 36, an air cushion with a height of only a few μm (e.g. 10 μm) is produced in the region between the air jets 36 and the load frame 26. In the present exemplary embodiment, six air jets 36 are provided on the holding frame 25, with one air jet 36 located in the region of each corner between the longitudinal struts 21 and transverse struts 22 and one air jet 36 located in the longitudinal middle of each longitudinal strut 21.

In the region of the transverse struts 22, the support rack frame 20 has a pocket-shaped recess 38, which is open toward the load frame 26. This recess 38 accommodates the coil arrangement 39 of a linear motor. A magnetic tape 40 is mounted in a recess of the load frame 26 oriented toward the coil arrangement 39. The recesses 38, 41 make it possible to minimize the overall height of the holding frame 25 even while accommodating a linear motor. A conduit 42 embodied in the support rack frame feeds into the recess 38 of the support rack frame 20 and contains an electric cable 43 that is connected to the respective coil arrangement 39. Between the magnetic tape 40 and the coil arrangement 39, there is an air gap. If the coil arrangement 39 is acted on with cur-rent, then in cooperation with the magnetic tape 40, a force is produced, which produces a linear movement of the load frame 26 in relation to the support rack frame 20. The linear motor, which includes the coil arrangement 39 and the magnetic tape 40, therefore constitutes a linearly adjusting positioner with which it is possible to adjust the relative position of the load frame 26 with regard to the support rack frame 20. The load frame 26 is permanently connected to the inner controt frame part 28 so that together with the load frame 26, the inner control frame part 28 is moved as well. Because of the swivel joints 30, 31, the movement of the load frame 26 and the inner control frame part 28 is limited to a predetermined movement range. This ensures that the distance between the coil arrangement 39 and the magnetic tape 40 is always small enough that the two elements 39, 40 cooperate as a linear motor.

The holding frame 25 has two such linear motors and linearly adjusting positioners; the two linear motors are each situated in the region of the transverse struts 22 of the support rack frame 20, between the respective support rack frame 20 and the load frame 26.

Adjacent to the two linear motors on the outside of the support rack frame 20 is fastened a respective support plate 44, which extends from the support rack frame toward the control frame 27 and covers a region of the load frame 26. On the inside of the support plates 44 is a respective optical sensor 45, which is oriented so that it faces the load frame 26. On the load frame 26 in the region of the sensor 45, a scale is provided; the scale can be engraved into the load frame. The scale can, however, also be a printed film that is glued to the load frame 26. The scale extends in the longitudinal direction of the respective linear motor. The sensor 45 can be used to detect the relative position of the load frame 26 and/or the inner control frame part 28 with regard to the support rack frame 20.

The holding frame 25 is arranged in the parallel tester 1 in such a way that the linear motors are oriented in the y-direction. The holding frame 25 thus constitutes a y-positioning device with two linearly adjusting positioners, which are arranged parallel to each other. Through different actuation of the two positioners, a rotational movement can be executed between the inner control frame part 28 and the support rack frame 20. One of the adapters 14, 15 is fastened to the control frame part 28. Consequently, the y-position and the rotational position of the respective adapters 14, 15 can be set by means of the linear motors in the parallel tester and thus in relation to a circuit board situated in one of the drawers 10, 11. It is thus possible to set both the rotational position and the y-position in a highly precise fashion.

The support racks 18 are each moved by an electric motor in the vertical direction (z-direction) and horizontal direction (x-direction) along guide rails (not shown). The motors are provided in the form of iron-core synchronous servomotors, which can produce powerful forces. These motors are embodied in the form of linear motors so that they can move the support racks 18 in linear fashion in the x-direction and z-direction.

The drawer mechanisms 8, 9 each have an electric motor for moving the carriages 55 along the guide rails 54, with which the drawers 10, 11 can be moved back and forth between the testing position and the exchanging position in the y-direction.

The parallel tester 1 also has a camera 46 in the region above the drawer mechanisms 8, 9 and a camera 46 in the region below them. The cameras 46 are each situated on a moving device 48 that is able to move the respective camera into a position adjacent to the testing positions of the two drawer mechanisms 8, 9 in order to be able to scan the circuit board in the testing position. The moving devices 48 each have a carriage 59, which can be moved in the x-direction along a rail 60 fastened to the longitudinal beams 51 of the base body 50. The cameras 46 are each fastened to brackets 49, which are supported on the carriage 59 so that they are able to move in the y-direction. By means of this, the cameras 46 can be situated in any position in the x-/y-plane above or below a circuit board in the testing position and it is possible to scan any region of the circuit board. In addition, the brackets 49 can be can be moved together with the respective cameras 46 back toward the rear wall 2 far enough that the moving devices 48 can be moved past the respective holding heads 12, 13 of the adapters 14 and test heads 16 in order to thus change positions with the respective holding devices 12, 13 above and below the drawer mechanisms 8, 9.

The parallel tester has a central control device 47 (FIG. 1), which automatically controls the movement of all of the moving parts of the parallel tester 1, the actuation of the cameras 46, the actuation of the other sensors, and the performance of electrical routines for the testing of circuit boards.

A method for testing a circuit board with the above-explained parallel tester 1 will be explained below:

In the present exemplary embodiment, the circuit board has 8 panels, which are arranged in two rows.

When the parallel tester 1 is switched on, first the two cameras 46 are calibrated to each other. In this case, one camera 46 detects the other camera 46 and it is possible to establish the position of the two cameras 46 relative to each other. Alternatively, it is also possible to place a perforated plate with a single small hole between the two cameras 46. The two cameras then each detect the hole. Since the two cameras are detecting the same hole at the same time, they can align their relative positions to each other.

The calibration of the cameras is preferably carried out at different positions in the parallel tester, which essentially correspond approximately to the positions in which the cameras are moved during operation for scanning circuit boards and/or the test adapters 14, 15. Corresponding calibration data are stored in memory for the different positions so that during subsequent operation, the images captured by the cameras can be positioned exactly relative to each other. By means of this, the coordinate systems defined by the two cameras 46 are calibrated to each other.

Each time the parallel tester is switched on or the test adapter 14 is exchanged, the positions or locations of the test adapters 14 are calibrated. To this end, the test adapters 14 are moved approximately into the testing positions in which they are supposed to contact a circuit board to be tested. In these testing positions, the adapters 14 are optically scanned by the respective cameras 46 and the actual positions of the adapters 14 are determined. These positions can be corrected as needed. In the respective testing positions, control information for controlling the movement of each test adapter 14 in the respective testing position is derived and stored in memory. With the help of this control information, the adapters 14 can be moved into the respective testing positions with a repeatability of one μm or a few μm, without requiring rescanning by one of the cameras 46. During the testing operation, it is therefore sufficient to control the movement of the test adapters 14 without a regulation by means of feedback.

After the cameras 46 and adapters 14 are calibrated, the actual testing operation begins.

Circuit boards to be tested are stacked in the hopper 3. The separating device 6 picks up the top circuit board from the stack and supplies it to a manipulation range of the robotic arm 7. The robotic arm 7 picks up the circuit board. It grips the board by means of vacuum grippers (not shown) and moves it to the drawer 10, 11 that is in the exchanging position.

The robotic arm 7 places the circuit board in the drawer 10, 11. This drawer is moved into the testing position.

The circuit board that has been moved into the testing position is scanned by the camera 46. For this purpose, the cameras are moved into the region adjacent to this circuit board. The cameras 46 each capture two images of the upper and lower side of the circuit board in each measurement position. These images are evaluated by the control device 47; prominent points (e.g. special marks or predetermined circuit board testing points) are extracted and their position in the parallel tester 1 is determined. This serves to determine the position of the circuit board to be tested in the parallel tester 1.

Then the cameras 46 are moved to the side.

The use of two cameras 46 to scan the upper and lower side of the circuit board to be tested can also serve to detect different distortions on the two sides of the circuit board, by means of which it is possible to discover offsets of the panels relative to the target position on the circuit board.

As the drawer is being moved into the testing position and as the individual measurement positions of the circuit board to be tested are being measured, the measurements are carried out on another circuit board in the other testing position. If the measurements on the other circuit board have been completed, then the corresponding drawer 10, 11 is moved into the exchanging position.

The two holding devices 12, 13, which each support one of the adapters 14 and one of the test heads 16, are then moved to the circuit board that is in the testing position and has already been measured; they are aligned with the respective adapter 14 in relation to a first panel of the circuit board and/or a first measurement position and are pressed against the circuit board. As a result, all of the circuit board testing points of this panel are contacted simultaneously by the adapters 14.

The alignment of the adapter 14 in the x-direction with regard to the respective panel of the circuit board is carried out by means of the holding device 12, 13, which moves the adapters 14 in the x-direction. In the present exemplary embodiment, the movement of the holding device in the x-direction by the control device 47 and the movement of the drawers 10, 11 are controlled without a control loop. This means that neither the position of the circuit board nor that of the adapters 14 is detected during the individual measurement procedures; instead, the movement of the circuit board and/or the adapters 14 is carried out solely based on previously detected and stored control information. As a result of this, the individual measurement procedures in different measurement positions can be carried out in very rapid succession. While the measurement procedures are being carried out on a circuit board that is in one of the two drawer mechanisms 8, 9, another circuit board in the other drawer mechanism 9, 8 is exchanged and is measured by means of the cameras 46. This optimizes the throughput of circuit boards to be tested since in order to execute the measurement procedures, it is only necessary to move the adapters 14 between the individual testing positions in a controlled way.

The alignment of the adapters 14 in the y-direction and of the relative rotational position with regard to the respective panel takes place by means of the linear motors, which are each composed of one of the coil arrangements 39 and one of the magnetic tapes 40. This movement is regulated in a closed control loop by means of the position signals produced by the sensors 45. In this case, the adapters 14 and test heads 16 are aligned inside the holding device 12, 13 by moving the inner control frame part 28 relative to the respective support rack frame 20. The alignment in the y-direction and/or with regard to the relative rotational position between the respective panel and the adapter can be carried out one single time for all of the panels of a circuit board if the deviation with regard to the y-direction and/or the relative rotational position is the same for all of the panels of a circuit board. This is the case if the deviation is primarily produced by the position of the circuit board in and of itself. If the deviations of the individual panels differ with regard to the y-direction and/or the rotational position, then it is advantageous to align the adapters with each panel separately.

Then the circuit board is tested. If it is a bare circuit board, then the individual conductors are tested for breaks and short circuits.

After the testing of the first panel, the adapters 14 are lifted up from the circuit board again and are moved to the second panel. The relative movement between the circuit board and the adapters 14 is executed on the one hand through a movement in the x-direction that is produced by movement of the corresponding support racks 18 in the x-direction or through a movement of the circuit board in the y-direction by means of the drawer mechanisms 8, 9. It is thus possible to successively test a plurality of panels that are arranged on a circuit board one after the other in a plurality of rows.

The adapters 14 can be aligned separately relative to the respective panels. Because the adapters 14 are not always aligned centrally relative to the circuit boards, during a testing procedure, the support rack 18 can protrude significantly from a circuit board to be tested. Consequently, the movement path of the drawer mechanisms 8, 9 between the testing position and the exchanging position is embodied as wide enough that in the exchanging position for the picking up of a circuit board, the support rack 18 does not cover over the receiving region of the drawers 10, 11.

If all of the panels of the circuit board to be tested have been tested, then their drawer 10, 11 is moved into the exchanging position. At the same time, the other drawer 11, 10 with another cir-cult board to be tested is in turn moved into the testing position. In the meantime, another circuit board to be tested has already been exchanged in the other drawer 11, 10 and the individual measurement positions of the additional circuit board to be tested have been measured.

The tested circuit board is picked up in the exchanging position by the second robotic arm 15 and is moved to one of the conveyor belts 4, 5 for good or bad circuit boards. If all of the panels of the circuit board have been tested, then the tested circuit board is placed onto the conveyor belt 4 for good circuit boards or else onto the conveyor belt 5 for bad circuit boards. The conveyor belts 4, 5 transport the circuit boards out of the housing of the parallel tester 1.

This special manipulation of the circuit boards in the parallel tester 1 by means of two independently actuatable drawers 10, 11 and adapters 14, which can be moved between the two testing positions, achieves the following advantages:
Through the independent movement of the drawers and adapters in orthogonal directions, it is possible for panels arranged in a plurality of rows on a circuit board to be tested one after another (stepping).
By means of the drawers, the actual testing procedure is completely decoupled from the manipulation, particularly the delivery and discharge of the circuit boards and the measurement of the circuit board. If a testing procedure in a testing position has been completed, then the testing procedure can be immediately started in the other testing position. Only the adapters have to be moved from the one testing position into the other testing position. During a testing procedure in the testing position of one of the two drawer mechanisms 8, 9, the tested circuit board is removed by means of the other drawer mechanism 9, 10, another circuit board to be tested is supplied, and this other circuit board is measured with the cameras.

Initial tests with prototypes of the parallel tester according to the invention have shown that it is more rapid than conventional parallel testers, in which the circuit boards are supplied to the testing position along a linear conveyor device and then transported away from the testing position.

This parallel tester is operated in such a way that during the testing operation, the air jets 36 continuously produce an air cushion between the support rack frame 20 and the load frame 26. By means of this, the adapter can be aligned very quickly with regard to its y-position and its rotational position. The guidance by means of the control frame parts 28, 29, which are guided with the swivel joints 30, 31 and are restricted in the movement range, achieves a quick and very exact alignment of the adapters in connection with the regulated positioning by means of the two linear motors.

In the context of the invention, however, it is also possible to interrupt the supply of compressed air as soon as the adapters are correctly aligned, as a result of which the load frames 26 come to rest on the support rack frame 20 and/or on the air jets 36 integrated into the support rack frame 20 and maintain their position through frictional engagement. This fixes the position of the adapters inside the holding device 12, 13.

The guidance of the adapter by means of the control frame parts 28, 29, which are guided in a restricted movement range by means of the swivel joints embodied as connecting pieces 30, 31, is embodied in a very simple mechanical way and fully complies with the necessary movement range for a fine adjustment of the adapters relative to the circuit board. In the context of the invention, it is also possible to guide the control frame 27 or the load frame 26 in a different way with regard to the support rack frame 20. Another form of guidance can also permit a larger movement play. Then, it can also be advantageous to adjust the air bearing in order to fix the position essentially after aligning the adapter relative to the circuit board.

The exemplary embodiment explained above has two adapters for simultaneously contacting an upper and lower side of a circuit board to be tested. This parallel tester can, however, also be embodied to contact only a single side; it is then possible to omit the second adapter with the other devices (second holding device, second test head, second camera).

The invention can be briefly summarized as follows:

The invention relates to a positioning device for a parallel tester, a parallel tester, and a method for testing a circuit board. According to a first aspect of the invention, for fine adjustment purposes, a positioning device is provided, which has two linearly adjusting positioners that are situated parallel to and spaced a predetermined distance apart from each other so that by actuating the two positioners, it is possible to execute both a linear movement and a rotational movement between a test adapter and a circuit board to be tested. In addition, a special manipulating mechanism is provided, having two conveyor devices for delivery and discharge of a circuit board to be tested in a first direction and having a positioning device for positioning the test adapter in a second direction that is approximately orthogonal to the first direction; the positioning device of the adapter can move the latter far enough that it can be positioned in the region of two test stations to which are coupled the devices for delivering and discharging the circuit board to be tested.

Reference Numeral List

| | |
|---|---|
| 1 | parallel tester |
| 2 | rear wall |
| 3 | hopper |
| 4 | conveyor belt for good circuit boards |
| 5 | conveyor belt for bad circuit boards |
| 6 | separating device |
| 7 | robotic arm |
| 8 | drawer mechanism |
| 9 | drawer mechanism |
| 10 | drawer |
| 11 | drawer |
| 12 | holding device |
| 13 | holding device |
| 14 | adapter |
| 15 | robotic arm |
| 16 | test head |
| 17 | gripper device |
| 18 | support rack |
| 19 | rear wall |
| 20 | support rack frame |
| 21 | longitudinal strut |
| 22 | transverse strut |
| 23 | side wall element |
| 24 | side wall element |
| 25 | holding frame |
| 26 | load frame |
| 27 | control frame |
| 28 | control frame part (inner) |
| 29 | control frame part (outer) |
| 30 | connecting piece |
| 31 | connecting piece |
| 32 | end strip |
| 33 | bores |
| 34 | positioning bores |
| 35 | intermediate strip |
| 36 | air jet |
| 37 | threaded pin |
| 38 | recess |
| 39 | coil arrangement |
| 40 | magnetic tape |
| 41 | recess |
| 42 | conduit |
| 43 | cable |
| 44 | support plate |
| 45 | sensor |
| 46 | camera |
| 47 | control device |
| 48 | moving device |
| 49 | bracket |
| 50 | base body |
| 51 | longitudinal beam |
| 52 | transverse beam |
| 53 | transverse beam |
| 54 | rail |
| 55 | carriage |
| 56 | rail |
| 57 | holding device carriage |
| 58 | linear drive |
| 59 | carriage |
| 60 | rail |
| 61 | x-axis |
| 62 | test specimen side |
| 63 | basic grid side |
| 64 | full grid cassette |
| 65 | adapter unit |
| 66 | adapter unit |
| 67 | spring pin cassette |
| 68 | contact pin |
| 69 | basic grid contacting plate |
| 70 | spring pin cassette |
| 71 | test needle |
| 72 | cable |
| 73 | pillar |

1-33. (canceled)

34. A positioning device for a parallel tester for testing circuit boards with a test adapter, which has a plurality of contact elements for simultaneously contacting several circuit board testing points of a circuit board to be tested, in which the test adapter has the capacity to be fastened to an inner holding piece of a holding device and the inner holding piece is supported so that it is able to move relative to the rest of the positioning device,
wherein as a bearing, only one or more swivel joints and/or one or more air bearings and/or one or more magnetic bearings is/are provided.

35. The positioning device according to claim 34,
wherein the holding device has an outer holding piece and the inner holding piece and outer holding piece are connected at least by means of a swivel joint.

36. The positioning device according to claim 35,
wherein between the inner and outer holding piece a middle holding piece is provided, with the middle holding piece being coupled to the inner and outer holding piece by means of a respective swivel joint.

37. The positioning device according to claim 34,
wherein an air bearing is provided for supporting the inner holding piece and/or the test adapter.

38. The positioning device according to claim 34,
wherein the positioning device is embodied as a y-positioning device with two linearly adjusting positioners for positioning the test adapter relative to the circuit board at least in a y-direction in the plane of the contact elements of the test adapter, in which the two linearly adjusting positioners are arranged approximately parallel to and spaced a predetermined distance apart from each other so that when the two positioners that are arranged in approximately parallel fashion are actuated differently, a relative rotary motion is executed between a test adapter fastened to the inner holding piece and a circuit board to be tested.

39. The positioning device according to claim 34,
wherein the positioning device has linearly adjusting positioners, which are embodied in the form of linear motors.

40. The positioning device according to claim 34,
wherein one or more displacement sensors for detecting a movement of the inner holding piece is/are provided, said one or more displacement sensors preferably being contactless displacement sensors and in particular, optical displacement sensors.

41. A parallel tester for testing circuit boards with a test adapter, which has a plurality of contact elements for simultaneously contacting several circuit board testing points of a circuit board to be tested, in which the parallel tester has a positioning device for positioning the test adapter relative to a circuit board to be tested,
wherein the test adapter has the capacity to be fastened to an inner holding piece of a holding device and the inner holding piece is supported so that it is able to move relative to the rest of the positioning device,
wherein as a bearing, only one or more swivel joints and/or one or more air bearings and/or one or more magnetic bearings is/are provided and is arranged to position a test adapter in the y-direction.

42. The parallel tester according to claim 41,
wherein the parallel tester has an x-positioning device, which is embodied for positioning the test adapter relative to the circuit board in an x-direction in the plane of the contact elements of the test adapter, which direction is approximately orthogonal to the y-direction.

43. The parallel tester according to claim 41,
wherein the parallel tester has a z-positioning device, which is embodied for positioning the test adapter relative to the circuit board in a z-direction, which is approximately orthogonal to the plane of the test adapter.

44. The parallel tester according to claim 41,
wherein the parallel tester has two test adapters, which are each arranged to test one side of a circuit board to be tested, with the two test adapters each being provided with the same positioning devices.

45. A parallel tester for testing circuit boards with a test adapter, which has a plurality of contact elements for simultaneously contacting several circuit board testing points of a circuit board to be tested,
wherein the parallel tester has a z-positioning device for moving the test adapter in a direction that is orthogonal to the plane of its contact elements, an x-positioning device for moving the test adapter in an x-direction in the plane of its contact elements, and a y-positioning device for moving the test adapter in a y-direction in the plane of its contact elements which direction is approximately orthogonal to the x-direction, and wherein the parallel tester has two testing stations which are offset in the x-direction and the x-positioning device is embodied with a movement path, which is large enough that the test adapter is movable between the two testing stations by means of the x-positioning device, and that a transporting means is provided on each testing station for delivery and discharge in the y-direction of a circuit board to be tested.

46. The parallel tester according to claim 45,
wherein the z-positioning device and the x-positioning device are embodied to move a holding device for holding the test adapter and the y-positioning device is integrated into the holding device and is embodied to move the test adapter relative to the holding device.

47. The parallel tester according to claim 45,
wherein the conveyor devices at the test stations are each embodied in the form of a drawer.

48. The parallel tester according to claim 34,
wherein the test adapter is a universal adapter, which maps a pattern of circuit board testing points of a circuit board to be tested onto a uniform grid of a universal test head.

49. The parallel tester according to claim 34,
wherein the test adapter is a dedicated test adapter, which has contact elements arranged in a pattern that corresponds to the pattern of the circuit board testing points of a circuit board to be tested, and the contact elements are connected directly to cables that lead to a set of testing electronics.

50. A parallel tester for testing circuit boards with a test adapter, which has a plurality of contact elements for simultaneously contacting several circuit board testing points,
in which the parallel tester has several moving devices for moving at least one component of the parallel tester, e.g. an adapter or a reception device for a circuit board to be tested,
wherein the parallel tester has a base body made of a mineral, ceramic, glass ceramic, or glass-like material or made of a concrete, with each moving device, which influences the relative position of both a circuit board to be tested and the test adapter, being fastened to the base body.

51. The parallel tester according to claim 50,
wherein the movement devices fastened directly to the base body each have one or more positioning devices, each positioning device being embodied to move the components in a movement direction and the positioning devices of each moving device being oriented orthogonal to each other.

52. The parallel tester according to claim 50,
wherein the parallel tester has a moving device for moving the adapter, a moving device for moving the receiving device for a circuit board to be tested, and a moving device for moving a camera.

53. The parallel tester according to claim 50,
wherein the base body is composed of granite, glass ceramic, or silica- and/or alumina-based ceramic.

54. The parallel tester according to claim 50,
wherein the base body is composed of a material whose thermal expansion coefficient is not greater than 5·10⁻⁶/K.

55. A parallel tester for testing of circuit boards with a test adapter, which has a plurality of contact elements for simultaneously contacting several circuit board testing points, in which the parallel tester has at least one moving device for moving the test adapter, a moving device for moving a receiving device for a circuit board to be tested, and at least one optical detection device,
wherein the parallel tester has a control device, which is embodied to detect a circuit board to be tested in different measurement positions by means of the optical detection device, with the location information of the circuit board with regard to the different measurement positions being stored in memory and the circuit board and test adapter being moved to the different measurement positions in order to perform a respective testing process in each of them.

56. The parallel tester according to claim 55,
wherein the optical detection device has at least one camera, which is arranged on the parallel tester in movable fashion.

57. The parallel tester according to claim 55, wherein the optical detection device has two cameras, which are arranged looking in opposite directions.

58. A method for calibrating a parallel tester,
wherein a detection device detects the location of a test adapter in different measurement positions, wherein control information for controlling the movement of the test adapter between the measurement positions is derived and stored in memory, and wherein the control information describes the movement of the test adapter in the individual measurement positions.

59. A method for calibrating a parallel tester according to claim 58,
wherein the parallel tester has an optical detection device, which includes two cameras and wherein the two cameras are calibrated to each other.

60. A method for calibrating a parallel tester according to claim 58,
wherein a parallel tester for testing if circuit boards with a test adapter is moved which has a plurality of contact elements for simultaneously contacting several circuit board testing points, in which the parallel tester has at least one moving device for moving the test adapter, a moving device for moving a receiving device for a circuit board to be tested, and at least one optical detection device,
wherein the parallel tester has a control device, which is embodied to detect a circuit board to be tested in different measurement positions by means of the optical detection device, with the location information of the circuit board with regard to the different measurement positions being stored in memory and the circuit board and test adapter being moved to the different measurement positions in order to perform a respective testing process in each of them.

61. A method for testing a circuit board,
wherein the circuit board is tested with a parallel tester for testing circuit boards with a test adapter, which has a plurality of contact elements for simultaneously contacting several circuit board testing points of a circuit board to be tested, in which the parallel tester has a positioning device for positioning the test adapter relative to a circuit board to be tested and is arranged to position a test adapter in the y-direction.

62. The method according to claim 61,
wherein the circuit board is only tested for breaks and/or short circuits.

63. The method according to claim 61,
wherein the circuit board is tested by means of a function test.

64. The method according to claim 61,
wherein a plurality of panels are successively tested through an incremental relative movement of the test adapter and the circuit board to be tested.

65. The method according to claim 61,
wherein a parallel tester is used having has a z-positioning device for moving the test adapter in a direction that is orthogonal to the plane of its contact elements, an x-positioning device for moving the test adapter in an x-direction in the plane of its contact elements, and a y-positioning device for moving the test adapter in a y-direction in the plane of its contact elements which direction is approximately orthogonal to the x-direction, and
wherein the parallel tester has two testing stations which are offset in the x-direction and the x-positioning device is embodied with a movement path, which is large enough that the test adapter is movable between the two testing stations by means of the x-positioning device, and that a transporting means is provided on each testing station for delivery and discharge in the y-direction of a circuit board to be tested and in one of the two test stations, a circuit board to be tested is actually tested while in the other test station, a circuit board to be tested is exchanged.

66. The method according to claim 65,
wherein in order to exchange one of the circuit boards, it is moved by the conveyor device in the y-direction from a testing position into an exchanging position.

67. The method according to claim 65,
wherein the y-positioning device has an air bearing device and during the movement of the test adapter in the y-direction, an air cushion is produced with the air bearing device and during the testing, no air cushion is produced so that the test adapter is fixed in position in the y-direction by means of frictional engagement.
